(19) United States
(12) Patent Application Publication
(10) Pub. No.: US 2026/0045455 A1
(43) Pub. Date: Feb. 12, 2026

(54) APPARATUS FOR TREATING SUBSTRATE

(71) Applicant: Samsung Electronics Co., Ltd., Suwon-si (KR)

(72) Inventors: Hankyoul MOON, Suwon-si (KR); Ingi KIM, Suwon-si (KR); Sangwoo BAE, Suwon-si (KR); Akinori OKUBO, Suwon-si (KR); Jungchul LEE, Suwon-si (KR)

(21) Appl. No.: 19/173,329

(22) Filed: Apr. 8, 2025

(30) Foreign Application Priority Data
Aug. 7, 2024 (KR) 10-2024-0105655

(51) Int. Cl. H01J 37/32

(52) U.S. Cl. CPC H01J 37/32697; H01J 2237/04735

(57) ABSTRACT

A substrate treating apparatus includes a support configured to support a substrate, a plasma source configured to excite a process gas and generate plasma, a grid assembly disposed to be spaced apart from the support in a first direction perpendicular to a surface of the support, the grid assembly being configured to extract and accelerate ions included in the plasma and generate ion beams, and a reflector disposed to be spaced apart from the grid assembly in the first direction, the reflector having a plurality of reflector holes configured to reflect and convert the ion beams into neutral beams, and a diameter of each of the plurality of reflector holes varies along the first direction.

### CROSS-REFERENCE TO RELATED APPLICATION

This application claims the benefit of Korean Patent Application No. 10-2024-0105655, filed on Aug. 7, 2024, in the Korean Intellectual Property Office, the disclosure of which is incorporated herein by reference.

### BACKGROUND

### 1. Field of the Invention

Example embodiments relate to a substrate treating apparatus, and more particularly, to an apparatus for treating a substrate using a neutral beam.

2. Description of the Related Art

Semiconductor devices may be manufactured through various processes such as photo, etching, a deposition process, and a cleaning process. Lately, the etching process and the deposition process are performed by generating ion beams from plasma. In particular, a manner of treating a substrate by converting the ion beams into neutral beams has also recently been suggested in order to minimize damage to the substrate and enable anisotropic treatment when conducting processes. However, when reflecting and converting an ion beam into a neutral beam, the neutralization efficiency of the ion beam may be improved, but the straightness of the neutral beam may decline. Specifically, as the neutralization efficiency of the ion beam is improved, the reflection frequencies of the ion beam also increase, which increases the divergence angle of the converted neutral beam and reduces straightness. Since the neutral beam increases further in divergence angle based on travel distances, conducting the etching process using this neutral beam may manufacture a semiconductor device having an asymmetric etching ratio. In other words, the neutralization efficiency of the ion beam and the straightness of the neutral beam may have a trade-off relationship.

### SUMMARY

An aspect provides a substrate treating apparatus that may efficiently treat a substrate.

Another aspect also provides a substrate treating apparatus in which both the neutralization rate of an ion beam and the straightness of a neutral beam may be improved.

Example embodiments are not limited to the technical features described above, and other technical features may be made apparent to those of ordinary skill in the art to which the present disclosure pertains from the following description and the accompanying drawings.

According to an aspect, a substrate treating apparatus includes a support configured to support a substrate; a plasma source configured to excite a process gas and generate plasma; a grid assembly disposed to be spaced apart from the support in a first direction perpendicular to a surface of the support, the grid assembly being configured to extract and accelerate ions included in the plasma and generate ion beams; and a reflector disposed to be spaced apart from the grid assembly in the first direction, the reflector having a plurality of reflector holes configured to reflect and convert the ion beams into neutral beams, wherein a diameter of each of the plurality of reflector holes varies along the first direction.

According to another aspect, a substrate treating apparatus includes a support configured to support a substrate; a plasma source configured to generate plasma; and a reflector disposed with the support in a first direction, the reflector having a plurality of reflector holes configured to reflect and convert an ion beam generated from the plasma into a neutral beam, wherein a diameter of each of the plurality of reflector holes varies along the first direction.

According to another aspect, a substrate treating apparatus includes a chamber having a treatment space and a plasma generation space; a support positioned within the treatment space and configured to support a substrate; an exhaust line configured to exhaust an atmosphere of the treatment space and the plasma generation space; a gas line configured to supply a process gas to the plasma generation space; a coil that is wound around the chamber and to which a high-frequency voltage is configured to be applied to excite the process gas and generate plasma; a grid assembly having a plurality of grid holes, the grid assembly being configured to extract and accelerate ions included in the plasma and generate an ion beam; and a reflector disposed to be spaced apart from the grid assembly in a first direction, the reflector having a plurality of reflector holes configured to reflect and convert the ion beam into a neutral beam, wherein the reflector is grounded, wherein each of the plurality of reflector holes includes a first region and a second region that are next to each other in the first direction, wherein the second region positioned to be closer than the first region to the support, wherein the first region has a shape in which a diameter of the first region decreases toward the support, and wherein the second region has a shape in which a diameter of the second region increases toward the support.

Additional aspects of example embodiments will be set forth in part in the description which follows and, in part, will be apparent from the description, or may be learned by practice of the disclosure.

According to example embodiments of the present disclosure, it is possible to efficiently treat a substrate.

Further, according to example embodiments of the present disclosure, it is possible to improve both the neutralization rate of an ion beam and the straightness of a neutral beam.

Effects of example embodiments are not limited to those described above, and other unstated effects may be clearly understood by those of ordinary skill in the art to which the present disclosure pertains from the appended claims.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 is a cross-sectional view schematically showing a substrate treating apparatus according to an example embodiment;

FIG. 2 is an exploded perspective view schematically showing a neutral beam generation part of FIG. 1;

FIG. 3 is a top plan view schematically showing a reflector of FIG. 1;

FIG. 4 is an enlarged view schematically showing part A of FIG. 1;

FIG. 5 is an enlarged view schematically showing part B of FIG. 1;

FIG. 6 is a diagram for illustrating a mechanism in which an ion beam is converted into a neutral beam in a reflector of FIG. 1;

FIG. 7 is a graph showing a distribution of a divergence angle of a neutral beam generated in a substrate treating apparatus of FIG. 1; and

FIG. 8 is a graph showing distributions of a neutralization rate of an ion beam and straightness rate of a neutral beam based on the thickness of a reflector of FIG. 1.

### DETAILED DESCRIPTION

Example embodiments of the present disclosure described below may be modified and implemented in various forms, and the present disclosure is not limited to the example embodiments described below. Terms used in example embodiments are selected from currently widely used general terms when possible while considering the functions in the present disclosure, excluding terms arbitrarily selected herein by the applicant and the meaning thereof described in detail. However, the terms may vary depending on the intention of a person skilled in the art, precedents, the emergence of new technology, and the like. In addition, the words and terminologies used in the specification and claims are not to be construed as limited to common or dictionary meanings but construed as including meanings and conceptions coinciding with the technical spirit of the present disclosure.

In the present disclosure, when a part is described as “comprising” or “including” a component, it does not exclude another component but may further include another component unless otherwise stated. Specifically, it should be understood that terms such as “comprise or include” and “have” are intended to indicate the presence of a feature, a number, a step, an operation, an element, a component, or a combination thereof which are described in the specification and not intended to previously exclude the possibility of the presence or addition of one or more other features, numbers, steps, operations, elements, components, or combinations thereof.

In the present disclosure, a singular expression includes a plural expression unless apparently otherwise defined by context. In addition, although the terms “first”, “second”, etc. may be used to describe various elements, these elements should not be limited by these terms, and the above terms may be used to distinguish one element from another. A first element may be referred to as a second element, and similarly, a second element may be referred to as a first element within the scope of the present disclosure. Further, the shape or size of elements in drawings may be exaggerated for clearer description. In addition, expressions such as “upper side,” “lower side,” “above,” “below,” “upper portion,” “lower portion,” “side surface,” “upper surface,” and “lower surface” hereinafter are represented based on a direction illustrated in a drawing and may be represented otherwise when the direction of a corresponding object changes.

An item, layer, or portion of an item or layer described as “extending” or as extending “lengthwise” in a particular direction has a length in the particular direction and a width perpendicular to that direction, where the length is greater than the width.

Hereinafter, example embodiments of the present disclosure will be described in detail with reference to the accompanying drawings so that those of ordinary skill in the art to which the present disclosure pertains may easily implement the present disclosure.

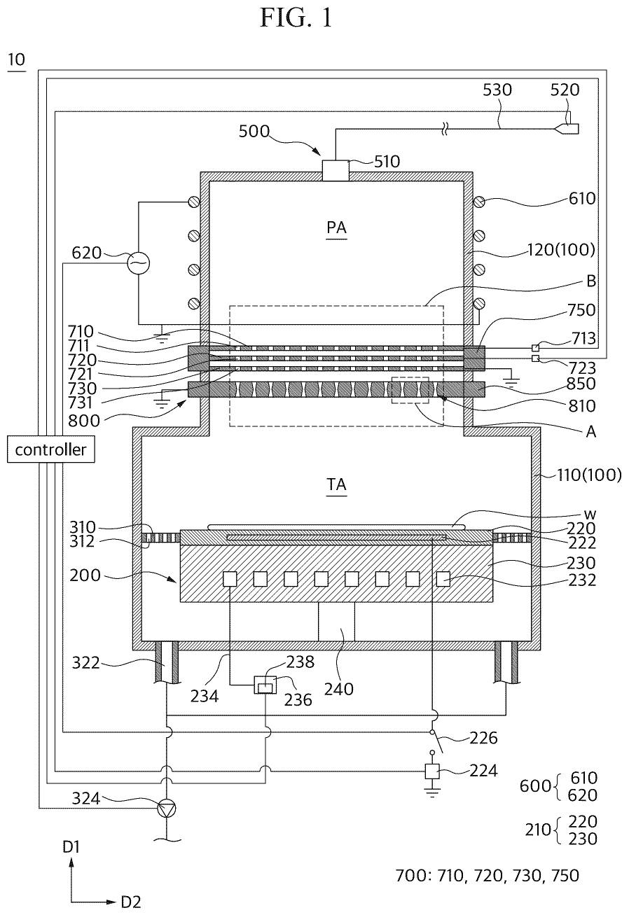

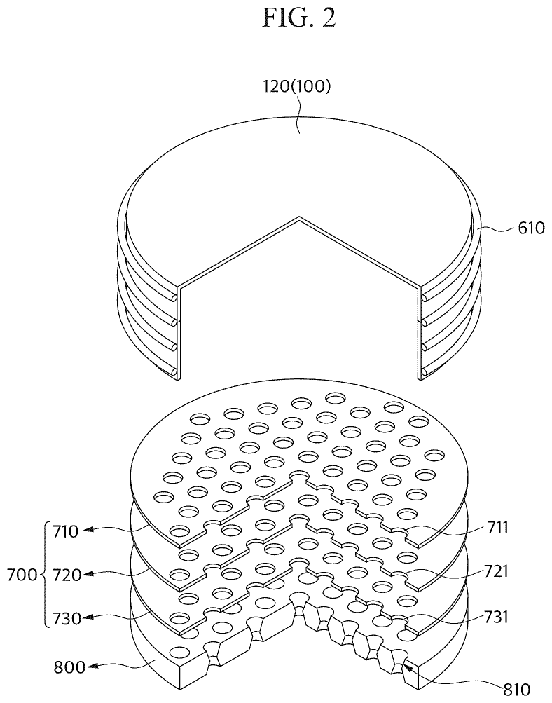

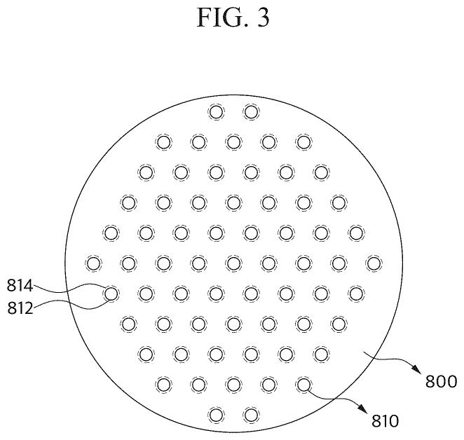

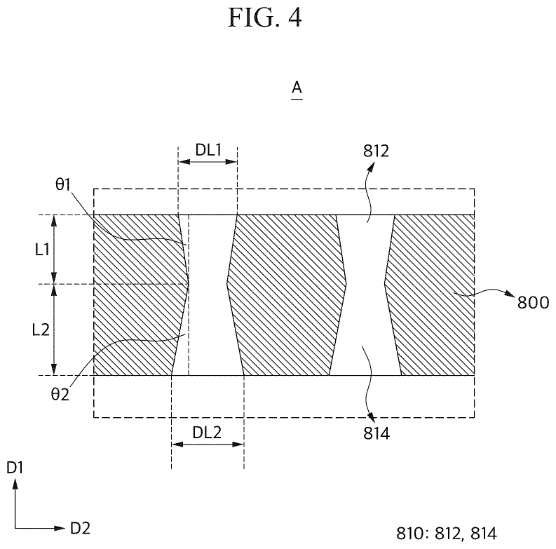

FIG. 1 is a cross-sectional view schematically showing a substrate treating apparatus according to an example embodiment. FIG. 2 is an exploded perspective view schematically showing a neutral beam generation part of FIG. 1. FIG. 3 is a top plan view schematically showing a reflector of FIG. 1. FIG. 4 is an enlarged view schematically showing part A of FIG. 1.

Hereinafter, a substrate treating apparatus 10 according to some example embodiments is described in detail with reference to FIGS. 1 to 4.

The substrate treating apparatus 10 according to some example embodiments may treat a substrate W using plasma. Specifically, in some example embodiments, the substrate treating apparatus 10 may treat the substrate W through the incidence of a neutral beam generated from plasma on the substrate W. According to some example embodiments, the substrate treating apparatus 10 may perform at least one process through the incidence of a neutral beam on the substrate W among, for example: an ashing process of removing a photoresist film formed on the substrate W, a deposition process of forming a thin film on the substrate W, an etching process of selectively removing a thin film on the substrate W, a process of modifying a surface of a thin film formed on the substrate W, a doping process of implanting ions, and a cleaning process of removing particles present on a substrate surface. However, the present disclosure is not limited to the above examples, and the substrate treating apparatus 10 according to some example embodiments may also be used in all kinds of processes of treating the substrate W through the incidence of a neutral beam on the substrate W.

In some example embodiments, the substrate treating apparatus 10 may include a chamber 100, a support unit 200, a gas supply unit 500, a plasma source 600, a grid assembly 700, and a reflector 800. According to some example embodiments, the support unit 200, the reflector 800, and the grid assembly 700 may be disposed or arranged in one direction. In addition, the support unit 200, the reflector 800, and the grid assembly 700 may be disposed sequentially. Hereinafter, for better understanding, a direction in which the support unit 200, the reflector 800, and the grid assembly 700 are disposed is defined as a first direction D1, and a direction perpendicular to the first direction D1 is defined as a second direction D2. In some example embodiments, the first direction D1 may indicate a direction perpendicular to a ground (e.g., a vertical direction), and the second direction D2 may indicate a direction parallel to the ground (e.g., a horizontal direction).

The chamber 100 according to some example embodiments may have a treatment space TA and a plasma generation space PA inside. According to some example embodiments, the chamber 100 may include a lower chamber 110 and an upper chamber 120. According to some example embodiments, the lower chamber 110 may have the treatment space TA inside. In addition, the upper chamber 120 may have the plasma generation space PA inside. The treatment space TA and the plasma generation space PA may be sealed so that an external environment may be blocked while the substrate W is treated therein. Further, in some example embodiments, the treatment space TA and the plasma generation space PA may be maintained substantially in a vacuum atmosphere while the substrate W is treated. The treatment space TA and the plasma generation space PA may be configured to be in fluid communication with each other. In some example embodiments, it may be understood that the treatment space TA is a space where the substrate W is positioned and predetermined treatment is conducted for the substrate W. In addition, it may be understood that the plasma generation space PA is a space where plasma is generated by the gas supply unit 500 and the plasma source 600 to be described below, a space where an ion beam is extracted from the generated plasma and accelerated by the grid assembly 700, and a space where the ion beam is converted into a neutral beam by the reflector 800. This is described below in detail.

The lower chamber 110 and the upper chamber 120 may be disposed (e.g., arranged) along the first direction D1. In addition, the lower chamber 110 may be disposed below the upper chamber 120 in the first direction D1. In some example embodiments, the lower chamber 110 and the upper chamber 120 may be formed to be integral. Further, in example embodiments, though not illustrated, the lower chamber 110 and the upper chamber 120 may be grounded.

In some example embodiments, the lower chamber 110 and the upper chamber 120 may have a substantially cylindrical shape. However, the shape of the lower chamber 110 and the upper chamber 120 is not limited thereto and may also be modified in various manners depending on design requirements. However, hereinafter, it is described as an example that the lower chamber 110 and the upper chamber 120 have a substantially cylindrical shape for better understanding. In some example embodiments, the lower chamber 110 may have a greater diameter than the upper chamber 120 in the second direction D2. However, the lower chamber 110 is not limited thereto and may have a diameter corresponding to (e.g., equal to or substantially equal to) the upper chamber 120. Further, in some example embodiments, inner sidewalls of the upper chamber 120 and the lower chamber 110 may be coated with a material that may prevent the inner sidewalls from being etched by plasma, an ion beam, and/or a neutral beam. For example, the inner sidewalls of the upper chamber 120 and the lower chamber 110 may be coated with a dielectric film such as ceramic. In addition, an opening (not shown) through which the substrate W is inserted and removed may be formed in a sidewall of at least one of the upper chamber 120 and the lower chamber 110. The opening (not shown) may be selectively opened and closed by a door assembly (not shown). Further, though not illustrated, a viewport (not shown) through which a process of treating the substrate W may be observed may be additionally formed in the sidewall of at least one of the upper chamber 120 and the lower chamber 110.

In the above examples, it is described as an example that the chamber 100 includes the lower chamber 110 and the upper chamber 120, but the present disclosure is not limited to this example.

The support unit 200 (e.g., support) according to some example embodiments may support the substrate W. According to some example embodiments, the support unit 200 may be an electrostatic chuck (ESC) that may chuck the substrate W using electrostatic force. However, the support unit 200 is not limited thereto and may mechanically support a side surface of the substrate W through a manner such as clamping, may mechanically support a lower surface of the substrate W by arranging a support pin, and may also support the substrate W through a vacuum adhesion manner. Hereinafter, it is described as an example that the support unit 200 is the ESC for ease of understanding.

According to some example embodiments, the support unit 200 may be disposed within the lower chamber 110. In other words, the support unit 200 may be positioned within the treatment space TA. In some example embodiments, the support unit 200 may include a chuck 210 and a support shaft 240. The chuck 210 according to some example embodiments may have a dielectric plate 220 and a base plate 230. The dielectric plate 220 according to some example embodiments may be positioned at an upper portion of the support unit 200. The substrate W may be placed on an upper surface of the dielectric plate 220. Further, in some example embodiments, the dielectric plate 220 may include a dielectric material. In some example embodiments, the dielectric plate 220 may be formed as a substantially circular plate shape. In an example illustrated in FIG. 1, it is illustrated that the dielectric plate 220 has a greater diameter than the substrate W but is not limited thereto. For example, the dielectric plate 220 may be formed to have a smaller diameter than the substrate W. Further, unlike the drawings, a focus ring surrounding the side surface of the substrate W may be additionally disposed at an edge area of the upper surface of the dielectric plate 220.

According to some example embodiments, an electrode 222 may be disposed inside the dielectric plate 220. For example, the electrode 222 may be embedded inside the dielectric plate 220. In addition, when viewed in the first direction D1 (e.g., in plan view), the electrode 222 may be disposed to overlap the substrate W substantially in an entire area of the substrate W and/or in an entire area of the electrode 222. Further, the electrode 222 may be electrically connected to a chuck power source 224. According to some example embodiments, the chuck power source 224 may be controlled by a controller and may be a direct current power source that applies direct current voltage to the electrode 222. In addition, a chuck switch 226 may be provided between the electrode 222 and the chuck power source 224, and may be controlled by a controller. The electrode 222 may be electrically connected to or disconnected from the chuck power source 224 depending on the on/off state of the chuck switch 226. For example, when the chuck switch 226 is on, direct current voltage may be applied to the electrode 222, and accordingly, electrostatic force may be applied between the electrode 222 and the substrate W and the substrate W may adhere to the dielectric plate 220.

In some example embodiments, a heater (not shown) may be further disposed inside the dielectric plate 220. For example, when the heater (not shown) is present, the heater may be disposed below the electrode 222 in the first direction D1. The heater may transfer heat to the dielectric plate 220 and raise the temperature of the substrate W, and thus, temperatures of the substrate W may be varied according to process requirements.

The base plate 230 according to some example embodiments may be disposed below the dielectric plate 220 in the first direction D1. In some example embodiments, an upper surface of the base plate 230 and a lower surface of the dielectric plate 220 may be bonded by an adhesive layer (not shown). The base plate 230 may have a substantially circular plate shape. In addition, the base plate 230 may have, but is not limited to, a diameter substantially corresponding to (e.g., equal to or substantially equal to) the dielectric plate 220. In some example embodiments, a flow path 232 may be formed inside the base plate 230. The flow path 232 according to some example embodiments may function as a path for a fluid to circulate. The flow path 232 may be configured as, but is not limited to, a single flow path having a spiral shape. For example, the flow path 232 may be configured as a plurality of flow paths. The flow path 232 may be connected to a fluid storage part 236 through a fluid supply line 234. A fluid may be stored in the fluid storage part 236. In some example embodiments, a fluid cooling part 238 may be positioned inside the fluid storage part 236. The fluid cooling part 238 may be controlled by a controller and may cool the fluid stored inside the fluid storage part 236. Unlike the above description, the fluid cooling part 238 may also be provided in the flow path 232. The cooled fluid may circulate along the flow path 232 and cool the base plate 230, and accordingly, the dielectric plate 220 and the substrate W may be cooled together. The fluid may be circulated, for example, by a pump that is controlled by a controller.

The support shaft 240 according to some example embodiments may support the chuck 210. The support shaft 240 may support a lower portion of the chuck 210. The support shaft 240 may have a substantially rod shape and may be placed on a bottom surface of the lower chamber 110.

In some example embodiments, a baffle 310 may be disposed between the sidewalls of the lower chamber 110 and the support unit 200. Specifically, the baffle 310 may be disposed between the inner sidewall of the lower chamber 110 and an outer side surface of the chuck 210. It is illustrated in FIG. 1 that the baffle 310 is in contact with an outer side surface of the dielectric plate 220 but the invention is not limited thereto. For example, the baffle 310 may also or instead be in contact with an outer side surface of the base plate 230. When viewed in the first direction D1 (e.g., in plan view), the baffle 310 according to some example embodiments may have a substantially ring shape. Accordingly, the baffle 310 may be disposed along a perimeter of the inner sidewall of the lower chamber 110 and a perimeter of the outer side surface of the chuck 210. In some example embodiments, at least one baffle hole 312 may be formed in the baffle 310. The baffle hole 312 may be a through hole that penetrates upper and lower surfaces of the baffle 310.

In some example embodiments, an exhaust line 322 may be connected to a bottom wall of the lower chamber 110. The exhaust line 322 according to some example embodiments may overlap the baffle 310 in the first direction D1. The exhaust line 322 may be connected to a depressurizing member 324. In some example embodiments, the depressurizing member 324 may be controlled by a controller and may be any one of known pumps that apply negative pressure to the treatment space TA. In some example embodiments, an atmosphere of the treatment space TA may be exhausted by the depressurizing member 324. In this process, a process gas, plasma, and byproducts generated while treating the substrate W and remaining in the treatment space TA may sequentially pass the baffle hole 312 and the exhaust line 322 described above and be discharged outside the substrate treating apparatus 10. In addition, the depressurizing member 324 may adjust the degree of the negative pressure applied to the treatment space TA and adjust the pressure of the treatment space TA according to process requirements.

The gas supply unit 500 (e.g., a gas line, a pump, and/or a blower) according to some example embodiments may supply a process gas to the plasma generation space PA. The process gas applied by the gas supply unit 500 may change in various manners depending on process types. For example, when performing an etching process on the substrate W, the process gas such as CF4 and SF6 may be supplied, and when performing a deposition process on the substrate W, the process gas such as SiH4 may be supplied, and when performing a cleaning process on the substrate W, the process gas such as NF3 and F2 may also be supplied, but the present disclosure is not limited thereto. In addition, the gas supply unit 500 may supply the plasma generation space PA with a carrier gas that contributes to the carrying and diluting of the process gas in addition to the process gas. For example, the carrier gas may include at least one of inert gases. In addition, the gas supply unit 500 may further supply a purging gas when conducting the exhaust in the plasma generation space PA and the treatment space TA after treating the substrate W is finished. For example, the purging gas may include nitrogen and/or argon gas.

In some example embodiments, the gas supply unit 500 may include a gas supply port 510, a gas supply source 520, and a gas supply line 530. In some example embodiments, the gas supply port 510 may be formed at the upper chamber 120. For example, the gas supply port 510 may be formed at a ceiling wall of the upper chamber 120 but the invention is not limited thereto. For example, the gas supply port 510 may also or instead be formed on the sidewall of the upper chamber 120. One end of the gas supply line 530 according to some example embodiments may be connected to the gas supply port 510, and the other end of the gas supply line 530 may be connected to the gas supply source 520. The gas supply source 520 may be controlled by a controller, may store gases and supply gases to the gas supply line 530, and may store various kinds of gases in addition to the process gas described above. According to some example embodiments, it may be understood that the gas supply source 520 may include a reservoir but include all known apparatuses that may store gases. In addition, though not illustrated, a mass flow controller (MFC) that may precisely control a flow amount of gases, a valve that may selectively block a flow of gases, and a filter removing byproducts that may be included in gases may be additionally provided in the gas supply line 530.

The plasma source 600, the grid assembly 700, and the reflector 800 to be described below may be collectively referred to as a neutral beam generation part that generates a neutral beam. The plasma source 600 according to some example embodiments may excite a process gas supplied to the plasma generation space PA to a plasma state. In some example embodiments, the plasma source 600 may be inductively coupled plasma (ICP), but the present disclosure is not limited thereto. For example, according to some other example embodiments, the plasma source 600 may be modified to capacitively coupled plasma (CCP) and microwave plasma. For example, when provided as CCP, the plasma source 600 may apply high-frequency power to the base plate 230 described above. Hereinafter, it is described as an example that the plasma source 600 according to some example embodiments is ICP for better understanding.

In some example embodiments, the plasma source 600 may include a coil 610 and a coil power source 620. In some example embodiments, the coil 610 may function as an antenna of the plasma source 600. The coil 610 may be disposed at an outer sidewall of the upper chamber 120. For example, the coil 610 may be wound a plurality of times to be wound in a substantially spiral (e.g., helical) form at the outer sidewall of the upper chamber 120. The coil 610 may be disposed at a height corresponding to the plasma generation space PA in the first direction D1. In other words, one end of the coil 610 may be positioned at a height corresponding to an upper end of the plasma generation space PA in the first direction D1, and the other end of the coil 610 may be positioned at a height corresponding to a lower end of the plasma generation space PA in the first direction D1.

In some example embodiments, the coil power source 620 may be electrically connected to the coil 610. According to some example embodiments, the coil power source 620 may be controlled by a controller and may apply high-frequency power to the coil 610. The high-frequency power applied to the coil 610 may form induced electric fields that have strong electric fields or radio-frequency (RF) electromagnetic fields in the plasma generation space PA. As described above, the process gas supplied to the plasma generation space PA by the gas supply unit 500 may obtain energy for ionization from the induced electric fields and be converted into a plasma state. In other words, the process gas may be excited and generate plasma in the plasma generation space PA.

In some example embodiments, the coil power source 620 may be connected to one end of the coil 610. In addition, according to some example embodiments, the other end of the coil 610 may be grounded. In some example embodiments illustrated in FIG. 1 and the like, it is illustrated that the coil power source 620 is connected to one end of the coil 610 positioned at an uppermost end and the other end of the coil 610 positioned at a lowermost end is grounded, but the present disclosure is not limited thereto. For example, the coil power source 620 may be connected to the other end of the coil 610 positioned at the lowermost end, and one end of the coil 610 positioned at the uppermost end may be grounded.

In addition, according to some example embodiments, an impedance matcher (not shown) and a switch (not shown) that selectively blocks high-frequency power applied to the coil 610 may be further provided between the coil power source 620 and the coil 610. The impedance matcher may match the impedance of the high-frequency power applied to the coil 610.

The grid assembly 700 according to some example embodiments may be provided in the upper chamber 120. In addition, the grid assembly 700 may extract and accelerate ions included in the plasma generated in the plasma generation space PA and generate an ion beam. According to some example embodiments, the grid assembly 700 may include a first grid 710, a second grid 720, a third grid 730, and a grid holder 750.

The first grid 710, the second grid 720, and the third grid 730 according to some example embodiments may have a substantially circular plate shape. For example, the first grid 710, the second grid 720, and the third grid 730 may have a shape extending along the second direction D2. In addition, the first grid 710, the second grid 720, and the third grid 730 may be disposed within the plasma generation space PA and may be arranged along the first direction D1. Further, the first grid 710 may be disposed to face the second grid 720 above the second grid 720 and the second grid 720 may be disposed to face the third grid 730 above the third grid 730.

In some example embodiments, the first grid 710, the second grid 720, and the third grid 730 may be disposed to be spaced apart from each other by a predetermined distance. Further, in some example embodiments, a first grid power source 713 may be connected to the first grid 710. In addition, a second grid power source 723 may be connected to the second grid 720, and the third grid 730 may be grounded. In some example embodiments, the first grid power source 713 and the second grid power source 723 may be controlled by a controller and may be direct current power sources that apply direct current voltage. According to some example embodiments, the first grid 710 may be a screen grid that extracts and accelerates ions from the plasma generated in the plasma generation space PA and generates an ion beam, and the second grid 720 may be an acceleration grid that further accelerates the ion beam. In addition, the third grid 730 may be a ground grid. However, the functions of the grids 710, 720, and 730 are not limited to the above examples. Further, unlike the above examples, direct current voltage may be applied to at least some of the first grid 710, the second grid 720, and the third grid 730, and the remaining grid or grids may be grounded. For example, direct current voltage may be applied to the first grid 710 and the third grid 730, and the second grid 720 may be grounded. Instead, according to some other example embodiments, the first grid 710 may be grounded, and direct current voltage may be applied to the second grid 720 and the third grid 730.

In addition, each of the first grid 710, the second grid 720, and the third grid 730 may include or consist of at least one of graphite, carbon graphite, molybdenum, titanium (Ti), stainless steel (SUS), copper (Cu), and aluminum (Al) or at least one metal alloy that is a combination thereof.

In some example embodiments, grid holes 711, 721, and 731 may be formed in the first grid 710, the second grid 720, and the third grid 730, respectively. Specifically, the first grid hole 711 may be formed in the first grid 710, the second grid hole 721 may be formed in the second grid 720, and the third grid hole 731 may be formed in the third grid 730. In this case, each grid hole 711, 721, and 731 may be a hole penetrating an upper surface through to a lower surface of each grid 710, 720, and 730. In some example embodiments, the first grid hole 711, the second grid hole 721, and the third grid hole 731 may be positioned to overlap each other in the first direction D1. For example, the first grid hole 711, the second grid hole 721, and the third grid hole 731 may be at the same horizontal position so that they are aligned vertically. Further, the first grid hole 711, the second grid hole 721, and the third grid hole 731 may be formed at a position to overlap the substrate W positioned in the treatment space TA in the first direction D1.

The grid holder 750 according to some example embodiments may fix the first grid 710, the second grid 720, and the third grid 730 on the upper chamber 120. The grid holder 750 may be provided on the sidewall of the upper chamber 120 and may penetrate the upper chamber 120 and support each grid 710, 720, and 730 and fix the position thereof. In this case, though not illustrated, a sealing member such as an o-ring may be disposed between the grid holder 750 and the upper chamber 120 so that the plasma generation space PA is sealed from an external space.

In the above examples, it is described as an example that the grid assembly 700 includes the first grid 710, the second grid 720, and the third grid 730 but is not limited thereto. For example, the grid assembly 700 may include N grids (N is a natural number that is 1, 2, 3, or 4 or more). In addition, some of the N grids may be grounded, and direct current voltage may be applied to others. Further, a positive voltage may be applied to some of the grids among the N grids, and a negative voltage may be applied to others, but the present disclosure is not limited thereto, and voltages of an identical type may be applied but voltages of different strengths may be individually applied to each grid.

The reflector 800 according to some example embodiments may be arranged with (e.g., disposed with) the grid assembly 700 in the first direction D1. For example, the reflector 800 may be disposed below the grid assembly 700 in the first direction D1, and accordingly, an upper surface of the reflector 800 may face a lower surface of the grid assembly 700. For example, the upper surface of the reflector 800 may face a lower surface of the third grid 730 according to some example embodiments. Since the reflector 800 according to some example embodiments may include a substantially identical or similar material to the first to third grids 710, 720, and 730 described above, duplicating descriptions thereof may be omitted.

In some example embodiments, a position of the reflector 800 may be fixed within the plasma generation space PA by a reflector holder 850. The structure, arrangement, and function of the reflector holder 850 may be substantially identical or similar to the grid holder 750 described above. In some example embodiments, the reflector 800 may be grounded. In addition, according to some example embodiments, the reflector 800 may have a substantially circular plate shape, but the present disclosure is not limited to this example. Further, in some example embodiments, the reflector 800 may be disposed to be spaced apart from the grid assembly 700 by a predetermined distance in the first direction D1. In addition, according to some example embodiments, the thickness of the reflector 800 may be greater than the thicknesses of each of the first grid 710, the second grid 720, and the third grid 730. For example, the thickness of the reflector 800 may be in a range of 10 millimeters (mm) to 40 mm.

According to some example embodiments, a reflector hole 810 may be formed in the reflector 800. The reflector hole 810 according to some example embodiments may be a hole penetrating upper and lower surfaces of the reflector 800 (e.g., from the upper surface of the reflector 800 to the lower surface of the reflector 800). In addition, a plurality of reflector holes 810 may be formed in the reflector 800. For example, the plurality of reflector holes 810 may be formed to be spaced apart from each other on the reflector 800. For example, the plurality of reflector holes 810 may be positioned to have radial symmetry with respect to a center point of the reflector 800. Further, each reflector hole 810 may be disposed to overlap a corresponding first grid hole 711, second grid hole 721, third grid hole 731, and the substrate W in the first direction D1. According to some example embodiments, the ion beam generated by passing through the first grid 710, the second grid 720, and the third grid 730 described above may be reflected by the reflector hole 810. While the ion beam strikes a surface of the reflector hole 810 and is reflected, a charge exchange may be conducted between the ion beam and the reflector 800, the ion beam may be converted into a neutral beam, and the neutral beam may pass through the reflector 800 and then be incident on the substrate W. This is described below in detail.

In some example embodiments, the reflector hole 810 may include a first region 812 and a second region 814. According to some example embodiments, the first region 812 may be an upper region of the reflector hole 810 divided in the first direction D1, and the second region 814 may be a lower region of the reflector hole 810 divided in the first direction D1. In other words, the second region 814 may be a region at a position more adjacent than the first region 812 to the substrate W (e.g., the support unit 200) in the first direction D1. For example, the first region 812 and the second region 814 may be next to each other in the first direction D1. According to some example embodiments, the first region 812 and the second region 814 may have a shape with a diameter varied depending on the height thereof. For example, the diameter of the reflector hole may vary along the first direction D1. Specifically, the first region 812 may have a shape in which a diameter gradually decreases toward the substrate W supported by the support unit 200, and the second region 814 may have a shape in which a diameter gradually increases toward the substrate W.

According to some example embodiments, a lowermost end of the first region 812 and an uppermost end of the second region 814 may be flush, and accordingly, a lowermost diameter of the first region 812 and an uppermost diameter of the second region 814 may be identical to each other. For example, the first region 812 may be continuous with the second region 814. In addition, according to some example embodiments, an uppermost diameter DL1 of the first region 812 may be less than a lowermost diameter DL2 of the second region 814 (see, e.g., FIG. 4). For example, the uppermost diameter DL1 of the first region 812 may be in a range of 0.75 mm to 1.5 mm. According to some example embodiments, an uppermost diameter of the first region 812 for enabling an ion beam entering the first region 812 to strike a sidewall of the first region 812 may be 1.5 mm.

In addition, according to some example embodiments, a first vertical distance L1 from an uppermost end to the lowermost end of the first region 812 in the first direction D1 may be less than a second vertical distance L2 from the uppermost end to a lowermost end of the second region 814 in the first direction D1. For example, the first vertical distance L1 may be in a range of 1.75 mm to 6.5 mm, and the second vertical distance L2 may be in a range of 5 mm to 25 mm. In some example embodiments, the first vertical distance L1 for enabling an ion beam entering inside the reflector hole 810 to strike first the sidewall of the first region 812 and then strike inside the second region 814 may be at least 6.5 mm. In addition, the first vertical distance L1 for enabling an ion beam entering inside the reflector hole 810 to strike the first region 812 may be at least 1.75 mm. Further, the second vertical distance L2 for enabling an ion beam entering inside the reflector hole 810 to strike the second region 814 may be at least 5 mm.

Further, in some example embodiments, a first angle θ1 that is an angle of inclination of the sidewall of the first region 812 may be less than a second angle θ2 that is an angle of inclination of a sidewall of the second region 814 with respect to a central axis of the reflector hole 810 parallel to the first direction D1 (e.g., with respect to the vertical direction). For example, the first angle θ1 may be in a range of 1 degree to 5 degrees, and the second angle θ2 may be in a range of 2.5 degrees to 6.5 degrees.

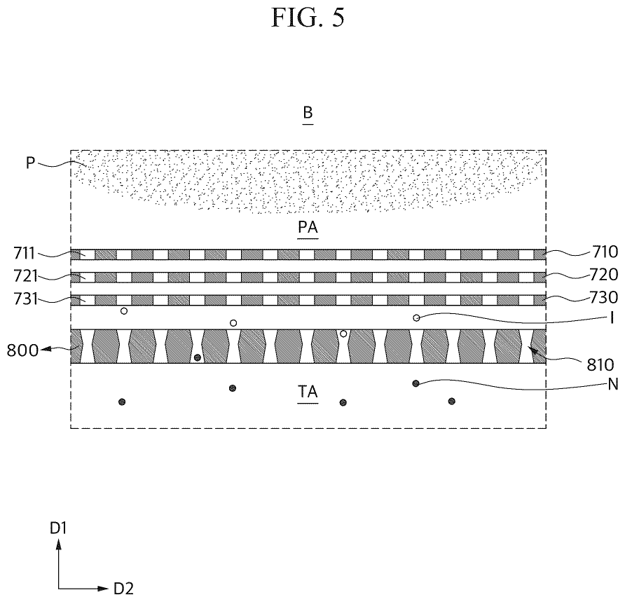

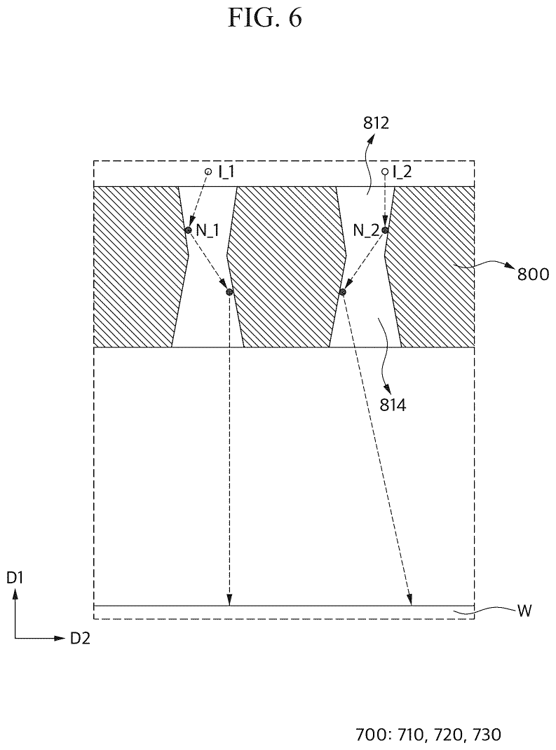

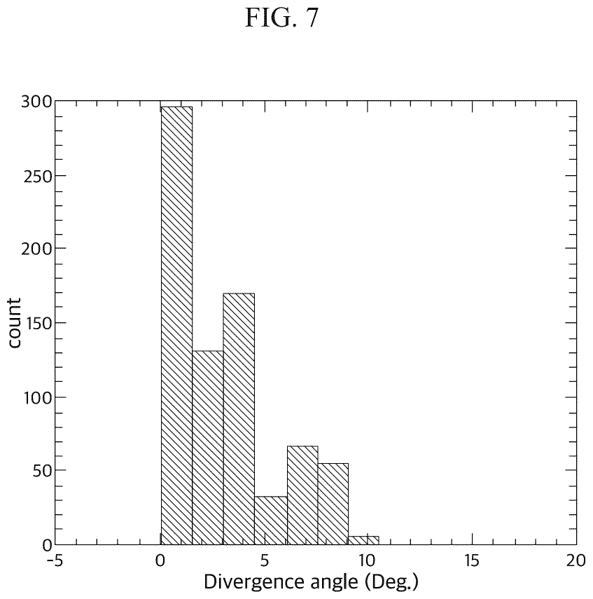

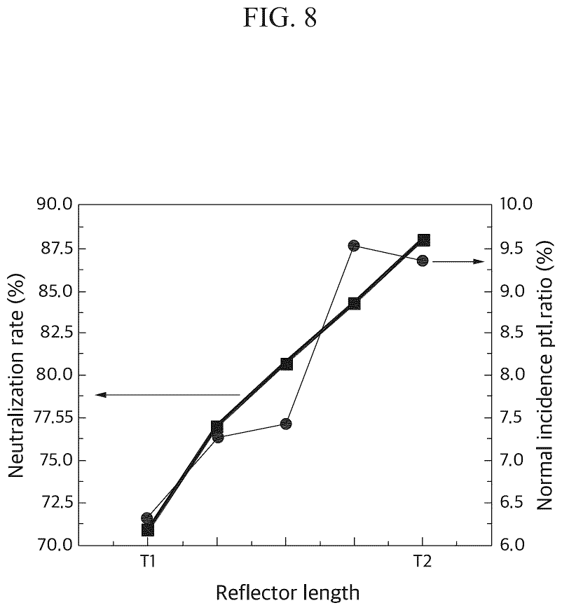

FIG. 5 is an enlarged view schematically showing part B of FIG. 1. FIG. 6 is a diagram for illustrating a mechanism in which an ion beam is converted into a neutral beam in a reflector of FIG. 1. FIG. 7 is a graph showing a distribution of a divergence angle of a neutral beam generated in a substrate treating apparatus of FIG. 1. FIG. 8 is a graph showing distributions of a neutralization rate of an ion beam and straightness rate of a neutral beam based on the thickness of a reflector of FIG. 1. In the graph of FIG. 7, a vertical axis may indicate the number of neutral beams incident on the substrate, and a horizontal axis may indicate an angle (a divergence angle) by which neutral beams incident on the substrate W are inclined with respect to the first direction D1. In the graph of FIG. 8, a left vertical axis may indicate a neutralization rate of ion beams converted into neutral beams, and a horizontal axis may indicate the thickness of the reflector 800. Here, T1 may be 10 mm and T2 may be 30 mm. Further, in the graph of FIG. 8, a right vertical axis may indicate an incidence ratio of neutral beams incident in a direction perpendicular to an upper surface of the substrate W.

Hereinafter, a mechanism in which a neutral beam is generated by the reflector 800 according to some example embodiments is described in detail. Hereinafter, reference numerals used in FIGS. 1 to 4 are used identically.

By an electric field formed in the plasma generation space PA (controlled, for example, by a controller) according to some example embodiments, a process gas may be excited and plasma P may be generated. According to some example embodiments, the plasma P generated within the plasma generation space PA may include ions, radicals, or the like. The ions included in the plasma P may be extracted by the grid assembly 700. Specifically, the ions included in the plasma P may be extracted into an ion beam I and accelerated while passing through the first grid hole 711. Then, the accelerated ion beam I may sequentially pass through the second grid hole 721 and the third grid hole 731 and be further accelerated to come out of the grid assembly 700.

Further, in some example embodiments, the ion beam I generated by sequentially passing through the grid holes 711, 721, and 731 may have an identical type charge (e.g., the ion beam I may be entirely positive or entirely negative), and accordingly, the ion beam I may enter the reflector hole 810 with a divergence angle of a predetermined angle due to repulsive force between charged particles thereof. For example, the ion beam I passing through the grid assembly 700 may have a divergence angle inclining by a predetermined angle with respect to the first direction D1 and, for example, may have a range of 3 degrees to 7 degrees with respect to the first direction D1. However, all the ion beams I passing through the grid assembly 700 may not have a divergence angle inclining by 3 degrees to 7 degrees with respect to the first direction D1, and some may enter the reflector hole 810 in a direction parallel to the first direction D1, in other words, a direction parallel to the central axis of the reflector hole 810.

In some example embodiments, when entering the reflector hole 810, the ion beam I may strike the surface of the reflector hole 810. Accordingly, a charge exchange between the ion beam I and the reflector 800 may be conducted as described above, and the ion beam I may be converted into a neutral beam N. The neutral beam N passing through the reflector 800 may flow into the treatment space TA and be incident on the substrate W, and may then be used to perform a predetermined treatment on the substrate W.

In some example embodiments, for example, some of the ion beams I passing through the grid assembly 700 may enter the reflector hole 810 with a divergence angle of a predetermined angle with respect to the first direction D1 as described above. For example, a first ion beam I_1 may enter the reflector hole 810 with a divergence angle inclining about 3 degrees to 7 degrees with respect to the first direction D1, and in this case, the first ion beam I_1 may strike first the sidewall of the first region 812 of the reflector hole 810 and be converted into a first neutral beam N_1. The first neutral beam N_1 may then strike the sidewall of the second region 814 secondarily. In this case, the straightness of the first neutral beam N_1 in the first direction D1 may be improved. For example, the direction of travel of the first neutral beam N_1 may become closer to the first direction D1 after striking the sidewall of the second region 814. For example, the first neutral beam N_1 may be incident upon the substrate W in the first direction D1, in other words, in a direction perpendicular to the upper surface of the substrate W due to a secondary strike on the sidewall of the second region 814. Further, in some example embodiments, some other (for example, a second ion beam I_2) of the ion beams I may enter the reflector hole 810 in a direction parallel to the first direction D1. In this case, the second ion beam I_2 may strike first the sidewall of the first region 812 of the reflector hole 810 and be converted into a second neutral beam N_2. Then, the second neutral beam N_2 may strike the sidewall of the second region 814 of the reflector hole 810 secondarily and be incident on the substrate W.

In other words, the first ion beam I_1 entering inside the reflector hole 810 with the divergence angle of the predetermined angle may be incident upon the substrate W in the direction perpendicular to the upper surface of the substrate W, and thus, the reflector 800 according to some example embodiments may improve the straightness of the neutral beam incident on the substrate W. Therefore, as illustrated in FIG. 7, the number of neutral beams incident upon the substrate W in the first direction D1, in other words, in the direction perpendicular to the upper surface of the substrate W by the reflector 800 according to some example embodiments may increase, which may improve the efficiency of treating the substrate W.

In an existing conventional reflector hole with a uniform width, when entering inside the reflector hole in a direction parallel to a central axis of the reflector hole, an ion beam may not be converted into a neutral beam but may instead pass through the reflector hole to be incident on the substrate W. However, according to some example embodiments, since the second ion beam I_2 entering inside the reflector hole 810 in the direction parallel to the central axis of the reflector hole 810 may strike the sidewall of the first region 812 of the reflector hole 810 and be converted into the second neutral beam N_2, the neutralization rate of the ion beam may be greatly improved. In other words, as illustrated in FIG. 8, for example, supposing that the first vertical distance L1 of the first region 812 is 6.5 mm and the second vertical distance L2 of the second region 814 is 25 mm as described above, the thickness of the reflector 800 may be about 30 mm, and in this case, both a ratio of neutral beams incident upon the substrate W in the direction perpendicular to the upper surface of the substrate W at T2 of the horizontal axis and a rate of ion beams neutralized into neutral beams may be improved. Therefore, due to the reflector 800 described above according to some example embodiments, both the neutralization efficiency of the ion beam and the straightness of the neutral beam may be improved.

The active and/or operable elements described above maybe controlled, for example, by a controller. Such elements may be, but are not limited to, the fluid cooling part 238, a pump that circulates cooled fluid through the flow path 232, the chuck power source 224, the chuck switch 226, the depressurizing member 324, the gas supply source 520, the coil power source 620, the first grid power source 713, and the second grid power source 723. Although not illustrated, the controller can include one or more of the following components: at least one central processing unit (CPU) configured to execute computer program instructions to perform various processes and methods, random access memory (RAM) and read only memory (ROM) configured to access and store data and information and computer program instructions, input/output (I/O) devices configured to provide input and/or output to the controller (e.g., keyboard, mouse, display, speakers, printers, modems, network cards, etc.), and storage media or other suitable type of memory (e.g., such as, for example, RAM, ROM, programmable read-only memory (PROM), erasable programmable read-only memory (EPROM), electrically erasable programmable read-only memory (EEPROM), magnetic disks, optical disks, floppy disks, hard disks, removable cartridges, flash drives, any type of tangible and non-transitory storage medium) where data and/or instructions can be stored. In addition, the controller can include antennas, network interfaces that provide wireless and/or wire line digital and/or analog interface to one or more networks over one or more network connections (not shown), a power source that provides an appropriate alternating current (AC) or direct current (DC) to power one or more components of the controller, and a bus that allows communication among the various disclosed components of the controller.

The detailed description above is made for illustrative purposes. Furthermore, the above descriptions represent the example embodiments of the present disclosure, and the present disclosure may be used in various other combinations, changes, and environments. In other words, the present disclosure may be changed or modified within the scope of the inventive concept disclosed in the specification, the equivalents to the written descriptions, and/or the technology or knowledge in the art. The above example embodiments describe the example embodiments for implementing the technical spirit of the present disclosure, and various changes may be made depending on the detailed application fields and purposes of the present disclosure. Therefore, the detailed description above is not intended to limit the present disclosure to the described example embodiments. In addition, the appended claims are to be construed as also including other example embodiments.

What is claimed is:

1. A substrate treating apparatus comprising:
a support configured to support a substrate;
a plasma source configured to excite a process gas and generate plasma;
a grid assembly disposed to be spaced apart from the support in a first direction perpendicular to a surface of the support, the grid assembly being configured to extract and accelerate ions included in the plasma and generate ion beams; and
a reflector disposed to be spaced apart from the grid assembly in the first direction, the reflector having a plurality of reflector holes configured to reflect and convert the ion beams into neutral beams,
wherein a diameter of each of the plurality of reflector holes varies along the first direction.

2. The substrate treating apparatus of claim 1, wherein each of the plurality of reflector holes includes a first region and a second region which are next to each other in the first direction,
wherein the first region has a shape in which a diameter of the first region decreases toward the support, and
wherein the second region has a shape in which a diameter of the second region increases toward the support.

3. The substrate treating apparatus of claim 2, wherein the second region is positioned to be closer than the first region to the support.

4. The substrate treating apparatus of claim 2, wherein the grid assembly includes a first grid, a second grid, and a third grid disposed to be spaced apart from each other sequentially in the first direction, and
wherein the third grid is disposed to face the reflector.

5. The substrate treating apparatus of claim 4, wherein a plurality of grid holes configured to extract and accelerate the ions are formed in each of the first grid, the second grid, and the third grid, and
wherein each of the plurality of grid holes overlaps a corresponding reflector hole of the plurality of reflector holes in the first direction.

6. The substrate treating apparatus of claim 2, wherein, for each of the plurality of reflector holes, an uppermost diameter of the first region is less than a lowermost diameter of the second region, and
wherein the uppermost diameter of the first region is in a range of 0.75 millimeters (mm) to 1.5 mm.

7. The substrate treating apparatus of claim 2, wherein, for each of the plurality of reflector holes, a vertical distance from an uppermost end of the first region to a lowermost end of the first region in the first direction is less than a vertical distance from an uppermost end of the second region to a lowermost end of the second region in the first direction.

8. The substrate treating apparatus of claim 2, wherein, for each reflector hole of the plurality of reflector holes, an angle of inclination of a sidewall of the first region of the reflector hole with respect to a central axis of the reflector hole is less than an angle of inclination of a sidewall of the second region of the reflector hole with respect to the central axis of the reflector hole.

9. The substrate treating apparatus of claim 2, wherein at least some of the ion beams generated by the grid assembly have a divergence angle inclining by a predetermined angle with respect to the first direction.

10. The substrate treating apparatus of claim 9, wherein the divergence angle is in a range of 3 degrees to 7 degrees,
wherein, for each reflector hole of the plurality of reflector holes, a first angle that is an angle of inclination of a sidewall of the first region of the reflector hole with respect to a central axis of the reflector hole is in a range of 1 degree to 5 degrees and a second angle that is an angle of inclination of a sidewall of the second region of the reflector hole with respect to the central axis of the reflector hole is in a range of 2.5 degrees to 6.5 degrees, and
wherein the first angle is less than the second angle.

11. The substrate treating apparatus of claim 10, wherein, for each of the plurality of reflector holes, a first vertical distance from an uppermost end of the first region to a lowermost end of the first region in the first direction is in a range of 1.75 mm to 6.5 mm and a second vertical distance from an uppermost end of the second region to a lowermost end of the second region in the first direction is in a range of 5 mm to 25 mm, and
wherein the first vertical distance is less than the second vertical distance.

12. The substrate treating apparatus of claim 4, wherein a thickness of the reflector is greater than a thickness of each of the first grid, the second grid, and the third grid, and
wherein the thickness of the reflector is in a range of 10 mm to 40 mm.

13. The substrate treating apparatus of claim 1, wherein the support is configured to support the substrate such that the plurality of reflector holes overlap the substrate in the first direction.

14. The substrate treating apparatus of claim 4, wherein each of the reflector and the third grid is grounded, and
wherein a direct current voltage is configured to be applied to each of the first grid and the second grid.

15. A substrate treating apparatus comprising:
a support configured to support a substrate;
a plasma source configured to generate plasma; and
a reflector disposed with the support in a first direction, the reflector having a plurality of reflector holes configured to reflect and convert an ion beam generated from the plasma into a neutral beam,
wherein a diameter of each of the plurality of reflector holes varies along the first direction.

16. The substrate treating apparatus of claim 15, wherein each of the plurality of reflector holes includes a first region and a second region which are next to each other in the first direction, wherein the second region is closer than the first region to the support,
wherein the first region has a shape in which a diameter of the first region decreases toward the support, and
wherein the second region has a shape in which a diameter of the second region increases toward the support.

17. The substrate treating apparatus of claim 16, wherein, for each of the plurality of reflector holes, an uppermost diameter of the first region is less than a lowermost diameter of the second region, and
wherein the uppermost diameter of the first region is in a range of 0.75 mm to 1.5 mm.

18. The substrate treating apparatus of claim 16, wherein, for each of the plurality of reflector holes, a vertical distance from an uppermost end of the first region to a lowermost end of the first region in the first direction is less than a vertical distance from an uppermost end of the second region to a lowermost end of the second region in the first direction.

19. The substrate treating apparatus of claim 16, wherein, for each reflector hole of the plurality of reflector holes, an angle of inclination of a sidewall of the first region of the reflector hole with respect to a central axis of the reflector hole is less than an angle of inclination of a sidewall of the second region of the reflector hole with respect to the central axis of the reflector hole.

20. A substrate treating apparatus comprising:
a chamber having a treatment space and a plasma generation space;
a support positioned within the treatment space and configured to support a substrate;
an exhaust line configured to exhaust an atmosphere of the treatment space and the plasma generation space;
a gas line configured to supply a process gas to the plasma generation space;
a coil that is wound around the chamber and to which a high-frequency voltage is configured to be applied to excite the process gas and generate plasma;
a grid assembly having a plurality of grid holes, the grid assembly being configured to extract and accelerate ions included in the plasma and generate an ion beam; and
a reflector disposed to be spaced apart from the grid assembly in a first direction, the reflector having a plurality of reflector holes configured to reflect and convert the ion beam into a neutral beam, wherein the reflector is grounded,
wherein each of the plurality of reflector holes includes a first region and a second region that are next to each other in the first direction, wherein the second region positioned to be closer than the first region to the support,
wherein the first region has a shape in which a diameter of the first region decreases toward the support, and
wherein the second region has a shape in which a diameter of the second region increases toward the support.
